(19) United States
(12) Patent Application Publication
(10) Pub. No.: US 2011/0165726 A1
(43) Pub. Date: Jul. 7, 2011

(54) METHOD AND ARRANGEMENT FOR PRODUCING A FUNCTIONAL LAYER ON A SEMICONDUCTOR COMPONENT

(75) Inventors: Knut Vaas, Alzenau (DE); Berthold Schum, Biebergemund (DE); Wilfried Schmidt, Schwaigern (DE); Dieter Franke, Vaals (NL); Ingo Schwirtlich, Miltenberg (DE)

(73) Assignee: SCHOTT SOLAR AG, Mainz (DE)

(21) Appl. No.: 13/059,383

(22) PCT Filed: Aug. 26, 2009
(86) PCT No.: PCT/EP09/61003

§ 371 Date: Mar. 21, 2011

(30) Foreign Application Priority Data
Aug. 28, 2008 (DE) 10 2008 044 485.5

(51) Int. Cl. H01L 31/18; B05C 11/00; B05C 3/02; B05B 1/00

(52) U.S. Cl. 438/97; 438/57; 118/63; 257/E31.043; 257/E31.001

(57) ABSTRACT

A method for producing at least one functional layer on at least one region of a surface of a semiconductor component by applying a liquid to at least the one region, where the functional layer has a layer thickness d₁ and the liquid required for forming the functional layer having the thickness d₁ has a layer thickness d₂. In order that functional layers having a desired thin and uniform thickness are produced in a reproducible manner, it is proposed that the liquid is applied to the at least one region of the surface in excess with a layer thickness d₃ where d₃>d₂ and that subsequently, either with the semiconductor component moved in translational fashion or with the semiconductor component arranged in stationary fashion, excess liquid is removed from the surface in a contactless manner to an extent such that the liquid layer has the thickness d₂ or approximately the thickness d₂.

The invention relates to a method for producing at least one functional layer on at least one region of a surface of a semiconductor component, particularly a solar cell, by applying a liquid to at least the one region. The invention further relates to an apparatus for producing at least one functional layer on at least one region of a semiconductor component.

More particularly, the invention relates to a method for producing at least one functional layer on at least one region of a surface of a semiconductor component, particularly a solar cell, by applying a liquid to at least the one region, wherein the functional layer has a layer thickness d₁ and the liquid required for forming the functional layer having the thickness d₁ has a layer thickness d₂.

To produce functioning or functional layers in the semiconductor component production industry, doping layers are applied in the substrate from the gas phase or from applied coatings, which contain suitable doping substances in selected concentrations. For these coatings, doping media or doping substances such as doping pastes can be used, for example. Following subsequent treatment at high temperatures, residues are then removed.

One significant criterion in this process is the adjustment of the doping substance in terms of the homogeneity, distribution and concentration thereof in the respective coating material, which can be a paste or a liquid. In the case of doping from the gas phase, the concentration of the active gas and the flow characteristics thereof ensure uniform distribution in the layer of the substrate to be coated that is near the surface.

The goal of the aforementioned process is to obtain a homogeneous coating. If structured coatings are desired, for example, printing or covering processes that are suitable for producing flat localized structures are used.

Common to all processes is that the thicknesses of the active layers can be effectively controlled only at high cost. This is true especially of thin layers, which are preferably applied by gas phase processes. Dipping and spraying processes, in contrast, produce relatively thick layers with low homogeneity.

WO 2006/131251 describes various methods for doping a semiconductor component. In these methods, doping sources are applied to the semiconductor component to be doped. A functional layer can be produced via CVD methods, screen printing methods or spray application, or by applying an aqueous solution with doping surfactants.

From U.S. Pat. No. 5,527,389 a method for producing a p-n junction in a semiconductor substrate is known. In this method a doping liquid is applied to the substrate via an ultrasonic spray, after which the liquid is dried and then subjected to a thermal treatment for doping the semiconductor component.

To remove etching or washing liquids from a substrate, said substrate is rotated while being heated, according to U.S. Pat. No. 6,334,902. The rotation exposes the substrate to severe mechanical stresses, which are unfavorable.

According to U.S. Pat. No. 4,490,192 a doping suspension is applied to a semiconductor by spraying or by a spinning process. The latter leads to undesirable mechanical stresses, and permits only low throughput.

The problem addressed by the present invention is that of further developing a method and an apparatus of the type described in the introductory section in such a way that functional layers having the desired thinness and uniform thickness can be produced in a reproducible manner, without any undesirable mechanical stresses acting on the substrate. The problem further involves enabling high throughput.

To solve the problem in terms of the method, it is essentially proposed that the following process steps be used:
applying the liquid to the at least one region of the surface in an excess amount and
removing excess liquid in a contactless manner from at least one region of the surface.

More particularly, it is provided that the liquid is applied to the at least one region of the surface in an excess amount, in a layer thickness d₃, in which d₃>d₂, and that subsequently, while the semiconductor component is either moved translationally or held stationary, excess liquid is removed from the surface in a contactless manner to such an extent that the liquid layer has the thickness d₂ or approximately the thickness d₂.

The invention therefore relates to a method for producing at least one functional layer on at least one region of a surface of a translationally moving or stationary semiconductor component, wherein the functional layer has a layer thickness d₁, the liquid required for forming the functional layer having the layer thickness d₁ has a layer thickness d₂, and the liquid that is applied in excess has a layer thickness d₃, with d₃>d₂, and wherein excess liquid is then removed from the surface in a contactless fashion, to such an extent that the liquid layer has the thickness d₂ or approximately the thickness d₂.

According to the invention, the functional layer is formed without the substrate being placed in rotation and thus exposed to undesirable centrifugal forces. At the same time, high throughput is possible because the substrate is either moved translationally or held stationary during formation of the layer thickness d₂.

In this process, it is provided particularly that excess liquid is removed in a contactless manner by directing at least one gas stream at the liquid, while the at least one gas stream and the semiconductor component are simultaneously moved in relation to one another, wherein the gas forms an angle β with the plane spanned by the surface, with 1°≦β≦90°.

Within this context, liquid in excess means that a liquid layer forms on the surface or on the region or regions to be provided with the functional layer, with the thickness of said liquid layer being greater than that of the functional layer to be produced, particularly prior to any thermal treatment.

According to the invention, a multistage process is provided, in which in a first process step, a liquid—such as a liquid film or a layer of liquid or liquids—is generated on the surface of the semiconductor component via spraying, misting, dipping, or other methods, for example. In this process, in principle the entire surface on which a functional layer will be produced is provided with the excess of liquid. However, it is also possible to provide only individual regions of the surface with the excess of liquid. This can be accomplished by providing those layers that will not be covered with liquid with hydrophobic properties.

The semiconductor components can have any shape; however they preferably have a plate-shaped geometry. Regardless of its shape, the surface to be equipped with the at least one functional layer can be smooth, rough or structured, chemically pretreated, hydrophilically or hydrophobically pretreated in a basic state that is appropriate to the material, or pretreated in some other manner.

The liquid is embodied on the basis of the function of the layer to be produced and can have various viscosities, can contain a solvent or be solvent-free, and can contain mixtures of various chemical constituents and compounds in various mixing ratios.

If a functional layer will be produced in regions of the surfaces that are hydrophobic, the liquid will contain at least one suitable substance that will enable the necessary wetting of the region by the liquid. The at least one gas stream is then inclined at an angle β from the plane spanned by the surface, with 1°≦β≦90°.

The semiconductor component is preferably covered with liquid on one side; however opposite surfaces may also be covered, in which case functional layers are formed particularly one after the other in sequence.

The liquid is applied to the surface in excess in one process step, wherein the semiconductor component is preferably dipped into the liquid or is coated in waves. Intensive spraying is another possibility. To establish the desired wetting properties, an exposure time of 1 second to 30 minutes, particularly 0.1 minute to 1 minute, is provided—although the invention is not limited to this.

If, rather than wetting the entire surface, only regions of the surface will be wetted with liquid, the desired regions may be pretreated accordingly, as mentioned, to adjust the wetting properties accordingly over the surface. For instance, hydrophobic or hydrophilic regions may be established locally, for example, distributed over the surface according to the desired structure.

When applying the liquid in excess, under certain circumstances an oxide layer that may be present on the surface can be removed or can be purposely applied.

In particular, when applying the liquid in excess, a layer having a thickness ranging from 1,000 μm to 100 particularly 250 μm to 100 is formed. The homogeneity of the corresponding layer should be <±10%, preferably between 5% and 10%.

Once the liquid has been applied in excess, in other words once a relatively thick liquid film has been formed, the excess liquid is removed in a contactless manner in a second process step. As a preparatory step in the contactless removal process, the semiconductor component can be placed at an incline so as to allow at least part of the excess liquid to run off. In particular, however, it is provided that excess liquid is removed via targeted exposure to a gas stream. In this process, the at least one gas stream removes liquid from the at least one region of the surface of the semiconductor component, down to a remaining layer thickness d₂, with 0.1 μm<d₂≦5 particularly 0.5 μm≦d₂≦1.95 with a homogeneity of ±10%, particularly ±3%.

In this case, the direction of the gas stream forms an angle β with the plane that is spanned by the surface of the semiconductor component, with 1°≦β≦90°.

To prevent liquid from flowing back while it is being removed, further developments of the invention provide for the semiconductor component to have a trailing edge at the rear end of the surface in the direction of relative movement, along which edge the liquid flows off. In this manner, any return flow of the film of liquid running off is prevented or significantly reduced. The trailing edge can be produced by passing it through an etching bath.

However, a trailing edge is not essential, because the liquid can “spray off” in all directions.

The gas stream should strike the at least one region at a speed of 1 m/s to 25 m/s. The gas volumetric flow rate per cm of semiconductor component transversely to the relative motion between the gas stream and the semiconductor component should be between 0.25 Nm³/h and 3.0 Nm³/h. The relative speed between the gas stream and the semiconductor component should be between 0.3 m/s and 3.0 m/s.

In particular, it is provided that the semiconductor component is exposed multiple times in sequence to a gas stream in order to remove liquid in successive steps. This is particularly advantageous when, after the layer of liquid has been applied in excess, the layer is thick enough that when it is struck by the gas a wave forms, which is undesirable during the final production of the desired layer thickness, because otherwise the required homogeneity cannot be ensured. In other words, the layer thickness must first be adjusted to a so-called initial layer thickness, in which wave formation is essentially suppressed. Once the initial layer thickness, which ranges from 21 μm to 99 μm, has been formed, the thickness is reduced by blowing off excess liquid, leaving a thickness of between 0.1 μm and 5.0 μm, particularly 0.9 μm and 1.9 μm, to produce the liquid functional layer.

A further development of the invention provides that the semiconductor component is moved multiple times in relation to a basic flow direction, at different angles relative to the at least one gas stream. This makes it possible to form strip-like and optionally intersecting functional layers, which are capable of functioning as passivation or masking layers.

However, even if the basic flow direction of the semiconductor substrate does not change, strip-like functional layers can be formed on the substrate by directing gas streams having different flow speeds or volumetric flow rates at the layers having liquid in excess, thereby removing the liquid in different quantities.

Once the semiconductor component has a liquid layer of a defined thickness as a result of the contactless removal of excess liquid, it can be subjected to a thermal treatment step. In this manner, more readily volatile constituents can first be removed by evaporation, allowing the remainder to react in a furnace atmosphere.

In particular, oxide layers can be formed, which react with the remaining components of the liquid. The formation of glass layers on semiconductor components containing silicon is specifically mentioned, the composition of which can be adjusted highly precisely using the method according to the invention. Nitridation or carbonization can also be performed in addition to oxidation, as long as the furnace atmosphere is chosen accordingly (N₂- or C-containing atmosphere such as methane, CO₂). The required reaction time is determined from the chemical properties of the involved substances and the surface morphology of the semiconductor component.

Thus according to the invention, semiconductor components can be provided with a functional layer that has a smooth or a textured surface.

However, in a thermal treatment step it is also possible to allow components that were already present in the original liquid, or that were created by reaction with the material of the semiconductor component, to diffuse into said material in a targeted manner. For example, phosphorous, carbon, boron, or similar elements can diffuse into the semiconductor material, for example, silicon, germanium, III/V-, II/VI-compounds.

If the goal is to form an n-conducting layer in a silicon substrate, for example, an aqueous phosphoric acid layer is applied as the liquid. If, in contrast, a p-conducting layer is desired, then an aqueous boric acid layer is used, for example.

Regardless of this, the functional layer of the desired thickness is to be altered during the thermal treatment step to a state that will enable efficient interaction in the boundary surface at an atomic level with the volume of the coated substrate. This includes, particularly, the diffusion of atomic constituents of the coating into the regions of the substrate that are close to the surface, which lead to an alteration in the chemical and physical properties of the material. This involves mechanical properties, such as hardness, but also electrical properties, such as conductivity, for example.

An apparatus for producing at least one functional layer on at least one region of a semiconductor component is characterized by the fact that the apparatus comprises a liquid application device and a gas stream delivery device, which can be adjusted relative to the semiconductor component and has a gas outlet opening, via which the semiconductor component can be acted upon by gas at an angle β from the plane that is spanned by the surface of the semiconductor component, with 1°≦β≦90°. It is also possible to rotate the gas stream delivery device about a vertical extending from the plane by an angle γ, with 0°≦γ≦90°. In this case, the gas outlet opening can be oriented toward the semiconductor component in such a way that the semiconductor component can be acted upon by gas in paths that run parallel to the direction of relative motion. According to one particularly notable embodiment of the invention, it is also possible for the gas to have different flow speeds and/or volumetric flow rates in the paths.

The liquid application device can comprise a dipping pan, a spraying device, or a wave application device.

The invention further provides that a thermal treatment device is positioned downstream of the gas stream delivery device.

One possible embodiment for applying the liquid layer in the first process step, in which the liquid is present in excess, can involve dipping, misting, spraying or other suitable methods, according to the invention. In this case, a large volume of liquid is applied, without requiring any control of the layer thickness.

In the corresponding wet treatment, a reaction of the liquid layer with the surface of the semiconductor component, in other words, for example, a chemical reaction, can be adjusted in such a way that said reaction produces an advantageous effect on the functioning of the component once its production is complete. Using appropriately reactive chemicals, the wetting ratios, or the wetting angles between liquid and substrate surface, are adjusted in a suitable manner. Appropriate acids, bases, reducing agents, oxidation agents and surfactants can be used for this purpose.

In particular, it is provided that in the aforementioned wet process step the semiconductor component slides along a roller track into a dipping pan, through which it is conveyed, moving continuously. The retention time should be between 1 second and 30 minutes. The dipping pan contains the liquid to be applied along with other reactive chemicals, if applicable. The liquid to be applied, having a suitably adjusted viscosity, is preferably a substance which is volatile at low or moderate temperatures, within the range of 100° C. to 800° C., in pure form or dissolved in a solvent, e.g., H₃PO₄, H₃BO₃, amines or similar substances. Reactive additional components in this liquid may be, for example, acids (HF, HCl, H₂SO₄), bases (NH₄OH, NR₄OH(R=alkyl, aryl), NaOH, KOH, Na₂CO₃, K₂CO₃, buffer substances (NH₄F, (NH₄)₃PO₄), oxidation agents (HNO₃, H₂O₂), reducing agents (N₂H₄, NH₂OH), etc.

More particularly, it is provided that a liquid containing at least one component from the group H₃PO₄, H₃BO₃, NH₄F, H₂O₂, HF, NH₄OH (amines, silazanes), Na₂CO₃, K₂CO₃ is used as the liquid, wherein the concentration of the at least one component is between 2 m (mass) % and 100 m %. Preferably, the invention provides that a 5 m % to 30 m % aqueous solution of H₃PO₄ or H₃BO₃ is used as the liquid. A 2 m % to 5 m % solution of H₃PO₄ or H₃BO₃ in alcohol, such as methanol, ethanol and/or isopropanol, for example, can also be used as the liquid.

Independently thereof, liquids with homogeneous and/or heterogeneous phases such as solutions, emulsions or suspensions can be used.

After leaving the dipping pan, the relatively thick liquid layer, in which liquid is consequently present in excess, as compared with the functional layer to be produced, can be diminished by placing the semiconductor component at an incline. However, this is not an essential feature.

Additional details, advantages, and features of the invention are specified not only in the claims, the features specified therein—alone and/or in combination—, but also in the following description of preferred embodiment examples illustrated in the set of drawings.

The drawings show:

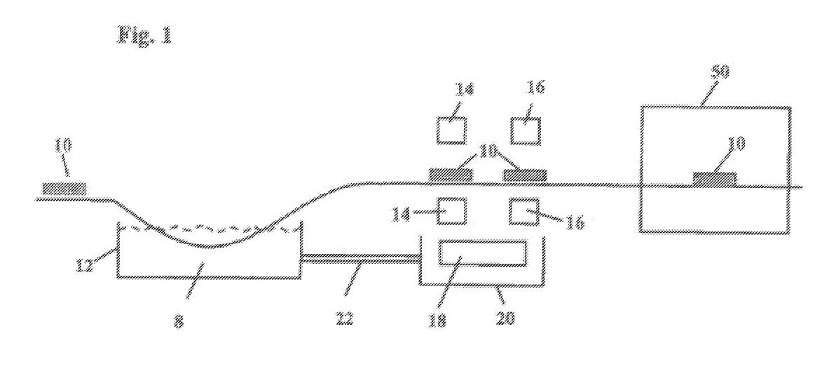

FIG. 1 a diagram illustrating the principle of an apparatus for producing a functional layer,

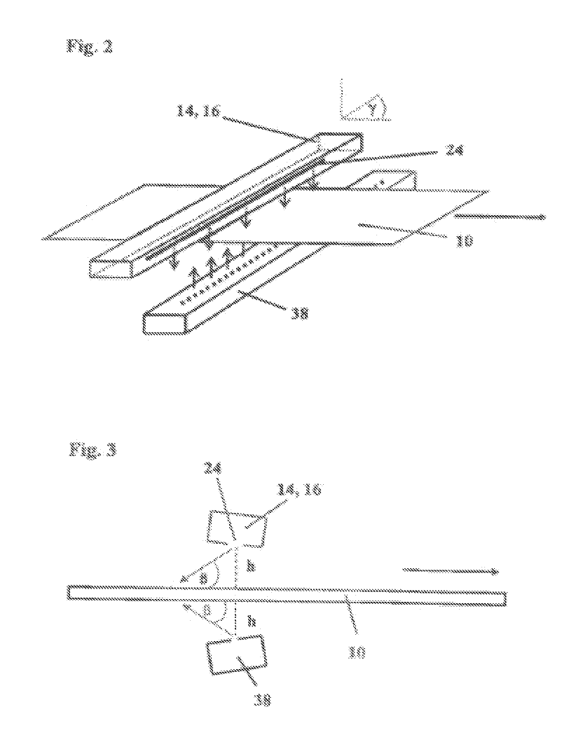

FIG. 2 a perspective illustration of an apparatus for removing liquid from a substrate,

FIG. 3 a side view of the apparatus according to FIG. 2,

FIG. 4 a plan view of an apparatus for the structured removal of liquid from a substrate,

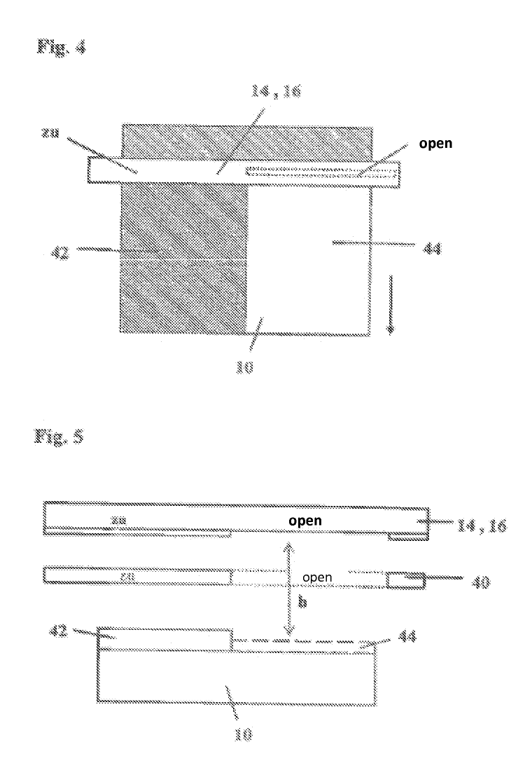

FIG. 5 a front view of the apparatus according to that of FIG. 4,

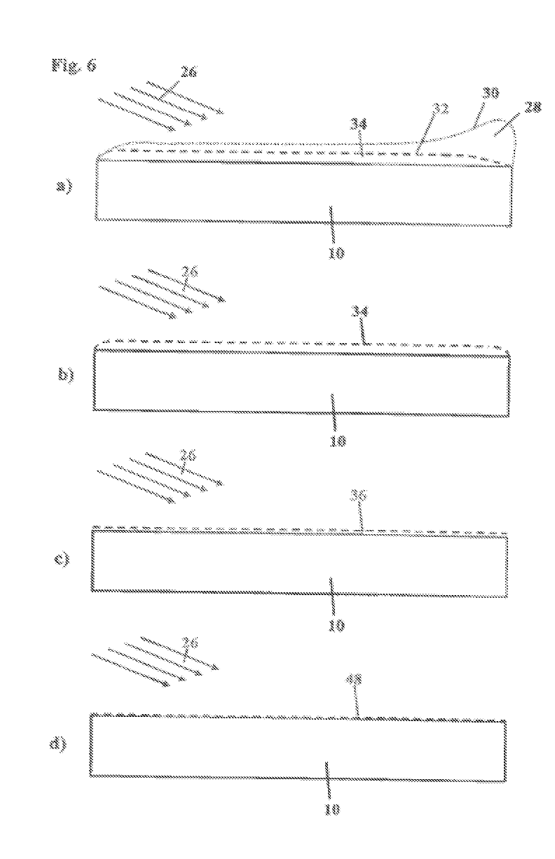

FIG. 6a-6d illustrations of a substrate to be provided with a functional layer showing the process as it advances,

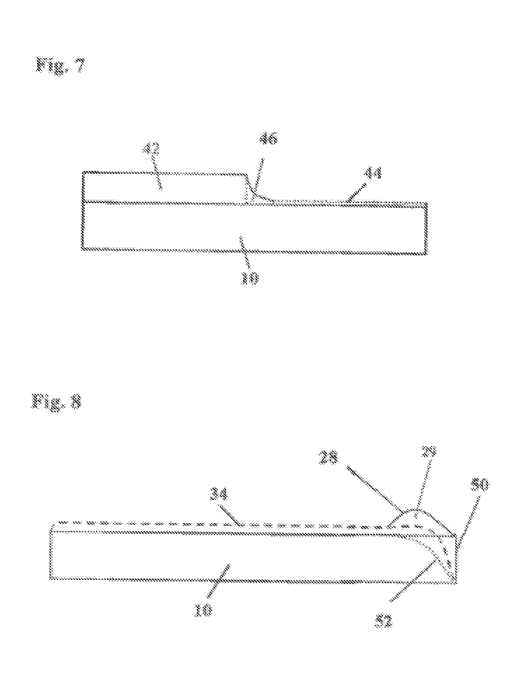

FIG. 7 the transitional area between layers of various thicknesses,

FIG. 8 the path of a liquid layer in the case of a trailing edge and

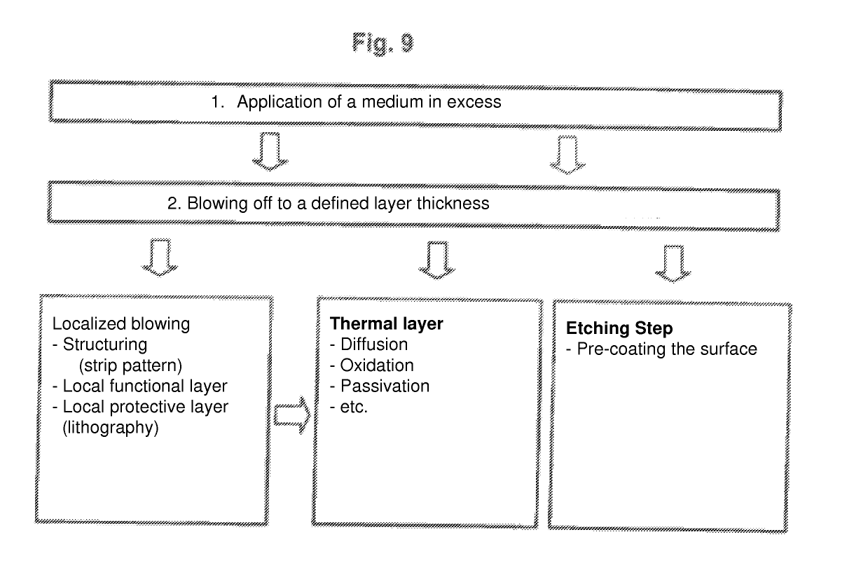

FIG. 9 a flow chart illustrating the process according to the invention.

With reference to the appended figures, the teaching according to the invention for producing one or more functional layers on a semiconductor substrate will be described. In this process, functional layers will be produced which have a homogeneous layer thickness preferably ranging from 0.1 μm to 5 μm. The layers will be produced with high reproducibility, and at a throughput rate that will enable mass production.

If, in reference to the embodiment examples, a thermal treatment is also taken into consideration, this is not an essential feature, although it is preferred.

The invention will also be specified in what follows on the basis of semiconductor components or substrates thereof which are intended particularly for solar cells, although the teaching of the invention is not limited to this.

With respect to the liquid layers to be applied to the substrates, it should be noted that desired viscosities can be established, in other words, viscous fluids are also included under the term liquids.

According to the invention, first a fluid layer is applied in excess to a substrate. Within this context, in excess means that the thickness of the layer is greater than is required for the desired thickness of the functional layer.

To apply an appropriate liquid layer in excess, substrates 10 are passed through a dipping pan 12 according to FIG. 1. A roller track or some similarly operating transport medium can be used for this purpose. The dipping pan 12 contains the liquid 8 to be applied, along with additional reactive chemicals, if applicable. A substance that is volatile at low to moderate temperatures, in other words preferably at temperatures of between 100° C. and 800° C., in pure form or dissolved in a solvent, for example, H₃PO₄, H₃BO₃, amines, or similar substances, is preferably used as the liquid. Reactive additional components in this liquid are, for example, acids (HF, H₁, H₂SO₄), bases (NH₄OH, HR₄OH(R=alkyl, aryl), NaOH, KOH, Na₄CO₃, K₂CO₃, buffer substances (NH₄F, (NH₄)₃PO₄), oxidation agents (HNO₃, H₂O₂), reducing agents (N₂H₄, NH₂OH), or similar substances, for example.

The retention time in the dipping pan 12 should preferably range from 0.1 min. to 1 min.

If the entire surface of the substrate 10 will be provided with a layer of liquid in excess, but the surface exhibits hydrophobic behavior, a surfactant is added to the liquid.

If the substrate 10 will not be treated over its entire surface, it can be appropriately pretreated at the desired locations in order to adjust its wetting properties. This means a localized establishment of, for example, hydrophobic or hydrophilic regions, which are distributed over the surface of the substrate according to the desired structure.

During its transport through the liquid 8, any oxide layers present on the substrate 10 can be removed, if applicable, or said layers can be purposely applied, depending upon the composition of the liquid, i.e., which substances it contains. The extent to which these are removed or applied, however, is based upon techniques that have long been known.

As it is exiting the dipping pan 12, or once it has exited the pan, the substrate 10 is preferably tilted in order to allow liquid to run off in a specified manner. To prevent the liquid from flowing back due to cohesive forces, the substrate 10 should be embodied as a trailing edge on the edge along which the liquid flows off, as is illustrated in FIG. 8. However, the trailing edge is not an essential feature.

To then reduce the thickness of the layer located on the substrate 10, the substrate 10 is passed beneath a gas stream, as is illustrated in principle in FIGS. 2 and 3. Corresponding gas stream infeed devices are identified in FIG. 1 by reference signs 14, 16. It is not necessary for the substrate 10 to be exposed to multiple gas streams in sequence. Instead, a single gas stream infeed device can suffice, if applicable.

To the side of and below the transport path of the substrates 10, a gas removal device 18 is located for suctioning off the gas that strikes the substrate 10 and is removed from or flows past the substrate 10. Below the transport path of the substrate 10, a liquid collection tray 20 is further provided, for collecting removed liquid and returning it via a line 22 to the dipping pan 12.

As is clear from FIGS. 2 and 3, a gas infeed device 14, 16 is located at least above the substrate 10, wherein said infeed device can have a slotted nozzle 24, which allows the gas to strike the substrate 10 in a targeted manner. In place of a slotted nozzle 24, perforated nozzles arranged in a row or offset from one another can also be used in a conventional manner. The perforated nozzles can have the same diameter or different diameters.

According to FIG. 6a, the substrate 10 has can have a relatively large layer thickness after the dipping process, which can lead to the incident air stream (arrow 26) creating a fluid wave 28, causing the layer thickness to be thinner in the front area than in the rear area. This situation is illustrated in principle by the dotted line 30 in FIG. 6a. To minimize this effect, a two-stage or multi-stage process is implemented in which a film is created, which has a uniform thickness over the entire region of the substrate 10 that is to be provided with a functional layer, as is clear from FIGS. 6b and 6c.

The undesirable wave 28 can be reduced or prevented by providing the substrate 10 with a trailing edge 52, as is illustrated purely in principle by FIG. 8. A suitable trailing edge 52 is actually a broken-off boundary edge 50 of the substrate 10. In other words, the trailing edge 52 has an essentially continuously curved shape. This can be achieved, for example, via etching. If the substrate 10 has a corresponding trailing edge 52, then the liquid wave 28 is avoided, as illustrated by the dashed illustration.

If layer thicknesses greater than 100 μm are present, the wave 30 illustrated in FIG. 6a can be produced, with the result that in a first step, the layer thickness must be reduced until the residual film thickness spreads again over the surface tension to form a homogeneous layer thickness (initial layer thickness). This is illustrated in FIG. 6a by the dashed line 32. To achieve a layer thickness profile having these specifications, the air stream delivered in the embodiment example of FIGS. 2 and 3 via the slotted nozzle 24 is adjusted in relation to the substrate 10 as follows:
Distance from the substrate surface (h) of 10-50 mm, preferably 20-30 mm,
Gas speed (v) of 1-15 m/s, preferably 5-10 m/s,
Gas speed homogeneity over the width of application, with a maximum fluctuation range of +/−10%, preferably less than +/−5%,
Volumetric flow per cm substrate width of 0.25-2.0 Nm³/h, preferably 0.5-1.5 Nm³/h,
Angle of incidence (β) of flow of 45°-70°, preferably 45°-60°,
Feed rate of substrate of 0.3-3.0 m/s, preferably 0.7-1.5 m/s,
Temperature of 20-30° C., preferably 20-25° C., with a homogeneity of +/−1-2° C.

When liquid has been removed from the substrate 10 on the basis of prescribed parameters, the result is a layer 34, the thickness of which lies within the range of 21 μm to 100 μm, preferably 30 μm to 50 μm.

To then adjust the reduction of the layer 34 to a residual film thickness ranging from 0.1 μm to 5 μm, preferably from 0.5 μm to 1.9 μm, the following parameters are preferably chosen:
Distance from the substrate surface (h) of 1-20 mm, preferably 5-10 mm,
Gas speed (v) of 5-25 m/s, preferably 10-18 m/s,
Gas speed homogeneity over the width of application, with a maximum fluctuation of +/−10%, preferably less than +/−5% (this is achieved by allowing the gas stream to spread unimpeded),
Volumetric flow per cm substrate width of 0.5-3.0 Nm³/h, preferably 1.5-2.0 Nm³/h,
Angle of incidence (β) of the flow of 70°-90°, preferably 80°-90°,
Feed rate of substrate of 0.3-3.0 m/s, preferably 0.7-1.5 m/s.

A check of the layers that form during the individual process steps can be performed by recording or measuring the weight or via optical processes such as ellipsometry. Layer homogeneity can be optically evaluated following the respective run-off step.

As is illustrated in FIG. 2, an air stream infeed device 38 can also be provided below the substrate 10, similar to the device provided above the substrate.

FIGS. 4 and 5 are intended to illustrate that the entire surface of the substrate 10 need not necessarily be acted upon by a uniform air stream. Instead, the functional layer or layers can be structured in localized areas. For instance, it is possible to block the stream of air delivered by the air stream infeed device 14, 16 in regions in which the layer thickness is not to be reduced.

For this purpose, the air stream can be shuttered. For instance, a shutter 40 or similar element can be provided between the air stream infeed device 14, 16 and the substrate 10. It is also possible to use air stream infeed devices that extend transversely in relation to the substrate 10, covering only a desired strip-like region.

As is clear from the figures, using an appropriate apparatus, a relatively thick layer 42 can be produced on the substrate 10 in the region in which the air stream is covered, and a thin layer 44 can be produced in the region that is acted upon by the air stream.

To ensure that the thick layer 42 does not extend over the entire surface of the substrate 10, the total layer thickness before the substrate 10 passes through the partially shuttered gas stream (FIG. 4, FIG. 5) should have a layer thickness of 15 μm+/−5 μm, in order to prevent the thicker layer 42 from flowing off as the layer thickness is being reduced to the layer 44. Irrespective of this, a transitional region 46, as is shown in principle in FIG. 7, results between the layers 42, 44.

To achieve a pre-thinning to the layer thickness 15 μm+/−5 μm, the following parameters must be maintained:
Distance from the substrate surface (h) of 5-20 mm, preferably 10-15 mm,
Gas speed (v) of 5-15 m/s, preferably 10-15 m/s,
Gas speed homogeneity over the width of application with a maximum fluctuation range of +/−10%, preferably less than +/−5%
Volumetric flow per cm substrate width of 0.5-2.0 Nm³/h, preferably 1.0-1.5 Nm³/h,
Angle of incidence (β) of the stream of 45°-90°, preferably 70°-80°,
Feed rate of the substrate of 0.3-3.0 m/s, preferably 0.7-1.5 m/s,
Temperature of 20-30° C., preferably 20-25° C., with a homogeneity of +/−1-2° C.

The substrate 10 is then passed through one of the gas stream infeed devices illustrated in FIGS. 4 and 5 with a partially blocked area or with shuttering, in order to achieve a layer thickness of between 0.1 μm and 5 μm, preferably between 0.5 μm and 1.9 μm, according to the prescribed parameters in the region acted upon by the gas stream, i.e., for the thickness of the layer 44.

With regard to the gas stream delivery device 14, 16, in other words particularly with regard to the nozzle bar, it should be noted that said bar is not only embodied as height adjustable in relation to the substrate and pivotable thereto about the angle β, but is also rotatable about a vertical that extends perpendicular from the plane spanned by the substrate surface. This is indicated by the angle γ in FIG. 2. In this, the nozzle bar can be rotated from a position perpendicular to the direction of transport of the substrate 10 (γ=0°) up to a parallel orientation (γ=90°).

Once the desired layer thickness (layer 36, 44) has been achieved, thermal treatment can be carried out according to FIG. 1.

In this, the substrate 10 can first be exposed to an elevated temperature, in order to evaporate readily volatile constituents. The remainder of the liquid is then allowed to react in the atmosphere of a furnace 46. In particular, in this phase oxide layers can be formed, which react with the remaining components of the liquid. In particular, the formation of glass layers on substrates that contain silicon is mentioned, the composition of which can be adjusted highly precisely by means of the described method. In addition to oxidation, nitridation or carbonization can also be carried out by means of this process step, by selecting the furnace atmosphere accordingly (e.g., N₂- or C-containing atmosphere, such as methane, CO₂).

The required reaction time in this process step is determined from the chemical properties of the involved substances and the surface morphology of the substrate 10.

Additionally, in a second temperature process a component that is present in the original liquid or is created by reaction with the substrate 10 can diffuse from the functional layer formed in this manner from the liquid layer 36 into the volume of the substrate 10 in a purposeful manner. Said component can be phosphorous, carbon, boron or similar elements which diffuse into the substrate material, such as silicon, germanium, III/V-, II/VI compounds.

If the liquid contains phosphoric acid, an n-conducting layer can be produced in a substrate consisting of silicon. If boric acid is used, a p-conducting layer can be formed.

With respect to the gas stream, it should be noted that preferred gases are air, N₂, noble gases or mixtures thereof with reactive gases for supporting the reaction with the surface or local change or viscosity, for example, HF, HCl, NH₃. The gas temperature can be set to between −70° C. and +300° C.

Drying in the furnace 46 should be carried out to such an extent that the thickness of the layer 48 is adjusted to between 0.01 μm and 0.3 μm.

It should further be mentioned that the reduction of the liquid layer thickness need not necessarily be carried out exclusively by impingement with a gas stream, if applicable after liquid is allowed to run off by tilting the substrate 10. Instead, to reduce the amount of liquid coating the substrate 10, thermal intermediate steps may also be used, which, by evaporating a part of the liquid, leads to a reduced quantity of liquid and, for example, support chemical reactions of the liquid with the component surface. It is also possible to allow purposefully added constituents to become concentrated in the liquid.

In what follows, preferred applications of functional layers on substrates made of silicon will be specified.

To generate masking or passivation layers, for example, after the functional layer is applied, a chemical reaction can be allowed to run with the silicon surface in a thermal step.

The following functional layers can be produced:

Functional layer SiO₂ (silicon dioxide or glasses)
e.g., by reaction with oxidation agents such as air, oxygen, ozone, hydrogen peroxide H₂O₂, nitric acid HNO₃;

Functional layer of glass-like substances (phosphoric and borosilicate compounds/glasses
e.g., by reaction with phosphoric acid, boric acid; optionally also in solutions with
alcohol such as methanol, ethanol, isopropanol;

Functional layer Si₃N₄ (silicon nitride) or Si_{X}N_{Y}
e.g., by reaction with ammonia gas or amine solutions or N₂;

Functional layer SiC (silicon carbide)
e.g., by reaction with carbonate solutions or gases such as CO₂, alkanes;

Functional layer formed as a primary layer, adhesive agents and/or other monomolecular layers,
e.g., surfactants, additives; HMDS (hexamethylene disilazane).

Functional layers in bulk silicon can be used for doping. This is achieved for generating a functional layer by subsequent additional reaction with the bulk silicon and by subsequent forcing in of the doping element:
Phosphorous: Generation of phosphosilicate compound on the surface
   e.g., phosphoric acid, phosphoric acid ester;
Arsenic: Generation of arsenic-containing glasses
   e.g., with arsenic acid, arsenic acid ester;
Boron: Generation with borosilicate compound
   e.g., with boric acid, boric acid ester;
Gallium: Generation of gallium silicate compound
   e.g., with gallate esters.

Following application, first a reaction with the silicon surface takes place, after which the formed doping substance is forced into the silicon in a second temperature step.

However, it is also possible to apply strip-like functional layers to the substrate, which intersect with one another, for example, or form other patterns. For this purpose, it is necessary to orient the substrate 10 in different directions in relation to a preferred direction of the substrate to the gas stream, which must be embodied in such a way that the surface of the substrate is preferably acted upon only in strips, with the result that only in these regions, layers of the desired thinness, taking into consideration the statements relating to FIGS. 4 and 5, can be formed.

In accordance with FIGS. 4 and 5 or in accordance with the localized structuring of the surface addressed above, a subsequent thermal step results in one part of the surface having a high quantity of the applied substance and one part of the surface having a low quantity of the applied substance. The concentration of the substance in the solution to be applied should then be selected such that the thin layer 44 that remains in localized areas does not reach the necessary active concentration in the subsequent thermal process step, i.e., for example, an electrical, chemical and/or structured modification of the relevant surface region. This is specified in greater detail in reference to the following example.

On the basis of the teaching according to the invention, an etching barrier made of silicon compound, such as silicon nitride, for example, is applied. The etching barrier is formed by the thick layer 42. If an etching medium is selected such that after a short time the thin layer 44 will be etched off but the thicker layer 42 will withstand the action for a longer period by the factor of the difference in layer thicknesses, then on the basis of the teaching of the invention, a masking is provided, which is formed solely by the application of the functional layers and the specified treatment thereof. However, it must be taken into account that the transitional area between the thin layer 44 and the thick layer 42, and therefore the masking, has no sharp contours (see FIG. 7), and is instead characterized by a more or less thick shaping of the thick layer 42 in the boundary areas.

The following should be noted regarding the substrate 10. As the substrate 10, p- or n-doped mono- or polycrystalline silicon disks having a disk thickness of between 40 μm and 500 μm can be used. In this context, a rectangular mono- or polycrystalline silicon disk having a disk thickness of between 40 μm and 500 μm can be used as the substrate 10.

More particularly, it is possible to use rectangular mono- or polycrystalline silicon disks having a disk thickness of between 40 μm and 220 μm and having an edge length of 100 mm to 400 mm, preferably 120 mm-160 mm, as substrates.

The method according to the invention or the process steps according to the invention are also illustrated in the self-explanatory flow chart of FIG. 9.

1. A method for producing at least one functional layer on at least one region of a surface of a substrate of a semiconductor component, particularly a solar cell, by applying a liquid to at least the one region, wherein the functional layer has a layer thickness d1 and the liquid required to form the functional layer having the thickness d₁ has a layer thickness d₂, characterized in that the liquid is applied in excess to the at least one region of the surface, in a layer thickness d₃, with d₃>d₂, and in that subsequently, while the semiconductor component is either moved translationally or held stationary, excess liquid is removed from the surface in a contactless manner to such an extent that the liquid layer has the thickness d2 or approximately the thickness d₂, wherein the contactless removal is achieved by directing at least one gas stream at the liquid, while the at least one gas stream and the semiconductor component are simultaneously moved in relation to one another.

2. The method according to claim 1, characterized in that a layer having functional chemical and/or physical properties is formed on the substrate, which properties, under the action of heat and/or a reactive gas atmosphere, lead to modified substrate properties from the surface of the substrate into the volume of the substrate, wherein the gas atmosphere consists of or contains oxygen, nitrogen, carbon dioxide, hydrocarbons.

3. The method according to claim 1, characterized in that
following the contactless removal of the excess liquid, the substrate is subjected to thermal treatment.

4. The method according to claim 1, characterized in that the functional layer is formed from multiple layers.

5. The method according to claim 1, characterized in that the functional layer reacts chemically with the material of the semiconductor component.

6. The method according to claim 1, characterized in that to apply the liquid in excess, the semiconductor component is dipped into the liquid, the liquid is applied to it in waves, and/or the component is sprayed with the liquid.

7. The method according to claim 1, characterized in that a liquid containing at least one component from the group H₃PO₄, H₃BO₃, NH₄F, H₂O₂, HF, NH₄OH, amines, silazanes, Na₂CO₃, K₂CO₃ is used as the liquid, wherein the concentration of the at least one component lies between 2 m (mass) % and 100 m %.

8. The method according to claim 1, characterized in that a 5 m % to 30 m % aqueous solution of H₃PO₄ or H₃BO₃ is used as the liquid.

9. The method according to claim 1, characterized in that a 2 m % to 5 m % solution of H3O₄ or H₃BO₃ in alcohol such as methanol, ethanol and/or isopropanol is used as the liquid.

10. The method according to claim 1, characterized in that a liquid that will etch the surface, such as a liquid containing HF or HNO₃ or KOH, is used as the liquid.

11. The method according to claim 1, characterized in that the at least one region of the surface of the semiconductor element has hydrophobic properties, to which a liquid containing at least one surfactant is applied.

12. The method according to claim 1, characterized in that the at least one gas stream removes liquid up to a remaining layer thickness of between 0.1 μm and 5 μm, particularly between 0.5 μm and 1.9 μm, from the at least one region of the surface.

13. The method according to claim 1, characterized in that the at least one gas stream is positioned inclined at an angle from the plane spanned by the surface, in which 1°≦β≦90°.

14. The method according to claim 1, characterized in that transversely to the direction of relative movement between the semiconductor component and the at least one gas stream, the semiconductor component is acted upon over at least a part of its entire transverse extension, by the at least one gas stream.

15. The method according to claim 1, characterized in that transversely to the relative movement between the semiconductor component and the at least one gas stream, the semiconductor component is acted upon by partial gas streams that have different gas speeds and/or gas volumetric flow rates.

16. The method according to claim 1, characterized in that the at least one gas stream is directed via an outlet opening, particularly in the form of a slotted nozzle or individual nozzles arranged along a straight line, toward the at least one region of the surface of the semiconductor component.

17. The method according to claim 1, characterized in that the gas stream strikes the at least one region of the surface of the semiconductor component at a speed v of 1 m/s≦v≦25 m/s.

18. The method according to claim 1, characterized in that the semiconductor component is moved multiple times and in relation to a basic preferred direction, at different angles relative to the at least one gas stream.

19. The method according to claim 1, characterized in that the semiconductor component is exposed multiple times to a gas stream or the gas stream, wherein to achieve a thickness of the functional layer of between 21 μm and 99 μm, preferably 30 μm and 50 μm, the following parameters are chosen:
distance from the substrate surface (h) of 10-50 mm, preferably 20-30 mm,
gas speed (v) of 1-15 m/s, preferably 5-10 m/s,
gas speed homogeneity over the width of application with a maximum fluctuation range of +/−10%, preferably less than +/−5%,
volumetric flow per cm substrate width of 0.25-2.0 Nm³/h, preferably 0.5-1.5 Nm³/h,
angle of incidence (β) of the stream of 45°-70°, preferably 45°-60°, wherein β is the angle between the direction of flow of the gas and the plane spanned by the substrate surface,
feed rate of the substrate of 0.3-3.0 m/s, preferably 0.7-1.5 m/s,
temperature of 20-30° C., preferably 20-25° C. with a homogeneity of +/−1-2° C.

20. Claim 1, characterized in that to generate a homogeneous layer thickness of the functional layer ranging from 0.1 μm to 5 μm, preferably 0.5 μm to 1.9 μm, the following parameters are chosen:
distance from the substrate surface (h) of 1-20 mm, preferably 5-10 mm,
gas speed (v) of 5-25 m/s, preferably 10-18 m/s,
gas speed homogeneity over the width of application with a maximum fluctuation range of +/−10%, preferably less than +/−5%,
volumetric flow per cm substrate width of 0.5-3.0 Nm³/h, preferably 1.5-2.0 Nm³/h, angle of incidence (β) of the stream of 70°-90°, preferably 80°-90°, wherein β is the angle between the direction of flow of the gas and the plane spanned by the substrate surface,
feed rate of the substrate of 0.3-3.0 m/s, preferably 0.7-1.5 m/s.

21. The method according to claim 1, characterized in that to generate a layer thickness of 15 μm+/−5 μm, the following parameters are chosen:
distance from the substrate surface (h) of 5-20 mm, preferably 10-15 mm,
gas speed (v) of 5-15 m/s, preferably 10-15 m/s,
gas speed homogeneity over the width of application with a maximum fluctuation range of +/−10%, preferably less than +/−5%,
volumetric flow per cm substrate width of 0.5-2.0 Nm³/h, preferably 1.0-1.5 Nm³/h,
angle of incidence (β) of the stream of 45°-90°, preferably 70°-80°, wherein β is the angle between the direction of flow of the gas and the plane spanned by the substrate surface,
feed rate of the substrate of 0.3-3.0 m/s, preferably 0.7-1.5 m/s,
temperature of 20-30° C., preferably 20-25° C., with a homogeneity of +/−1-2° C.

22. The method according to claim 1, characterized in that the surface of the substrate is provided with a locally structured functional layer, wherein the surface is covered with the functional layer over an area of between 1%-50%, preferably between 5% and 20%, of the surface.

23. The method according to claim 1, characterized in that a semiconductor component having a substrate in the form of a mono- or polycrystalline silicon disk is used.

24. The method according to claim 23, characterized in that a disk which is produced according to the EFG process is used as the polycrystalline silicon disk.

25. The method according to claim 1, characterized in that p- or n-doped mono- or polycrystalline silicon disks having a disk thickness of between 40 μm and 500 μm are used as the substrate.

26. The method according to claim 1, characterized in that rectangular mono- or polycrystalline silicon disks having a disk thickness of between 40 μm and 500 μm are used as the substrate.

27. The method according to claim 1, characterized in that rectangular mono- or polycrystalline silicon disks having a disk thickness of between 40 μm and 220 μm and having an edge length of 100 mm to 400 m, preferably 120 mm-160 mm, are used as substrates.

28. The method according to claim 1, characterized in that the liquid etches the surface as it is being applied.

29. The method according to claim 1, characterized in that regions of the surface of the semiconductor component are acted upon by gas streams having different gas volumetric flow rates and/or gas speeds.

30. The method according to claim 1, characterized in that a gas consisting of or containing oxygen, nitrogen, carbon dioxide, hydrocarbon, noble gas is used as the gas.

31. The method according to claim 1, characterized in that air is used as the gas of the gas stream.

32. The method according to claim 1, characterized in that a reactive gas is used as the gas of the gas stream.

33. The method according to claim 32, characterized in that the reactive gas contains HF, HCl, HNO₃ and/or NH₃.

34. The method according to claim 1, characterized in that a semiconductor component that has a trailing edge at its rear end in the direction of flow of the excess liquid that is to be removed, which edge is embodied particularly as a broken-off edge or has a curved or bent shape, is used as the semiconductor component.

35. The method according to claim 1, characterized in that the functional layer is a doping substance source for generating a diffusion profile in the semiconductor component.

36. The method according to claim 35, characterized in that the diffusion profile forms a pn-junction in the semiconductor component.

37. An apparatus for producing at least one functional layer on at least one region of a semiconductor component (10) by applying a liquid to the region using a liquid application device (12) provided in the apparatus, wherein the functional layer has a thickness d₁ and the liquid required to form the functional layer having the thickness d₁ has a layer thickness d₂,
characterized in that liquid is applied to the at least one region in excess via the liquid application device (12), in a layer thickness d₃ with d₃≧d₂, in that the apparatus comprises a gas stream delivery device (14, 16), which can be adjusted relative to the semiconductor component (10) and which has one or more gas outlet openings, in that, while the semiconductor component is being moved translationally or held stationary, excess liquid is removed from the region in a contactless manner by means of the gas stream delivery device, to such an extent that the liquid layer has the thickness d₂ or approximately d₂, wherein the gas outlet openings direct gas toward the semiconductor component over the plane spanned by the surface of the semiconductor component, said gas being directed at an angle β, with 1°≦β≦90°, and the angle being inclined in relation to the plane.

38. The apparatus according to claim 37, characterized in that the gas stream delivery device (14, 16) can be rotated about a vertical projecting from the plane, by the angle γ, in which particularly 0°≦γ≦90°.

39. The apparatus according to claim 37, characterized in that the gas outlet opening is oriented toward the semiconductor component (10) in such a way that the semiconductor component is acted upon by gas in paths that extend parallel to the direction of movement of the semiconductor component relative to the gas outlet opening.

40. The apparatus according to claim 39, characterized in that in the paths, the gas has different flow speeds and/or gas volumetric flow rates that are different from one another.

41. The apparatus according to claim 37, characterized in that the liquid application device (12) is a dipping pan.

42. The apparatus according to claim 37, characterized in that the liquid application device comprises a spray device.

43. The apparatus according to claim 37, characterized in that the liquid application device comprises a wave application device.

44. The apparatus according to claim 37, characterized in that a gas removal device (18) is positioned in the region of the gas stream delivery device (14, 16), below and/or adjacent to the semiconductor component (10) to be acted upon by the gas.

45. The apparatus according to claim 37, characterized in that a liquid collection device (20) that is connected to the liquid application device (12) is positioned below the semiconductor component (10) in the region of the gas stream delivery device (14, 16).

46. The apparatus according to claim 37, characterized in that the gas outlet opening (24) can be adjusted transversely to the direction of movement between the substrate (10) and the gas outlet opening direction.

47. The apparatus according to claim 37, characterized in that the distance between the gas stream delivery device (14, 16) and the surface of the semiconductor component (10) can be adjusted.
